(19) United States
(12) Patent Application Publication
(10) Pub. No.: US 2014/0218054 A1
(43) Pub. Date: Aug. 7, 2014

(54) Electrode Configuration, Hand-Held Device as Well as Method for the Detection of a Touch of a Hand-Held Device

(71) Applicant: Microchip Technology Incorporated, Chandler, AZ (US)

(72) Inventors: Holger Steffens, Munchen (DE); Andreas Güte, Hong Kong (HK)

(21) Appl. No.: 13/877,542

(22) PCT Filed: Oct. 4, 2011
(86) PCT No.: PCT/EP2011/067283

§ 371 Date: Feb. 10, 2014

(30) Foreign Application Priority Data
Oct. 4, 2010 (DE) 10 2010 041 957.5

(51) Int. Cl. G01R 1/067

(52) U.S. Cl. CPC G01R 1/06766
USPC 324/660

(57) ABSTRACT

An electrode configuration for a capacitive sensor device of a hand-held device for the touch detection of a user has at least one transmitting electrode, at least one receiving electrode and at least one first field measuring electrode. The electrode configuration enables a detection of the position of the hand-held device relative to the body of a user. A method for the detection of a touch of a hand-held device by a user can also be provided, wherein the method is adjusted to detect the position of the hand-held device relative to the body of a user.

### CROSS-REFERENCE TO RELATED APPLICATIONS

This application is a U.S. National Stage Application of International Application No. PCT/EP2011/067283 filed Oct. 4, 2011, which designates the United States of America, and claims priority to DE Application No. 10 2010 041 957.5 filed Oct. 4, 2010, the contents of which are hereby incorporated by reference in their entirety.

### TECHNICAL FIELD

The present invention relates to an electrode configuration for a capacitive sensor device of a hand-held device for the touch detection of a user. Furthermore, the invention relates to a hand-held device with an electrode configuration according to the present invention. Furthermore, the invention relates to a method for the detection of a touch of a hand-held device with an electrode configuration according to the present invention by a user.

### BACKGROUND

Sensor devices which can be arranged at a hand-held device in order to detect an approximation to the hand-held device by a hand are known from prior art. For example it is known to arrange capacitive sensors at a hand-held device in order to detect an approximation of a hand to the sensor electrodes due to a change of the dielectric properties in the area of the sensor electrodes of the capacitive sensor. Such capacitive sensors known from prior art do not only enable the detection of an approximation of a hand to the hand-held device but also the detection of a gripping of the hand-held device with the hand. This way it is possible to activate the hand-held device once a gripping of the hand-held device with a hand is detected.

However, it is disadvantageous that not every gripping of the hand-held device means that the hand-held device is actually going to be used. For example, cell phones are often carried in the hand without being used immediately. A detection of a gripping of the cell phone with the method according to prior art would lead to an activation of the cell phone in any case. The activation of the cell phone would, among others, lead to increased energy consumption.

It is known to use a timer to overcome this disadvantage. The cell phone or the hand-held device is activated after the detection of a gripping and a timer is started simultaneously. Once the timer reaches a predetermined value without the cell phone being used, the cell phone is turned off again. However, this only partially avoids the disadvantage of the unnecessary energy consumption, since the cell phone is activated initially before it is deactivated again once the timer reaches a certain value.

Furthermore, it is known from prior art to provide a position sensor in addition to the capacitive sensor for the detection of a gripping, providing information whether the cell phone is in an upright position, which usually indicates that the cell phone is in use. However, it is disadvantageous that two different sensor technologies are used, which results in higher material costs. Furthermore, the additional position sensor does not ensure that the cell phone is actually used, even if it is held in an upright position; for example, when the cell phone is held in the hand with the display towards the palm of hand.

### SUMMARY

According to various embodiments, the intention of using an electrical hand-held device can be detected more reliably.

According to various embodiments, an electrode configuration for a capacitive sensor device of a hand-held device for the touch detection of a user by means of a hand-held device with an electrode configuration according to various embodiments as well as a method for the detection of a touch of a hand-held device.

An embodiment provides an electrode configuration for a capacitive sensor device of a hand-held device for the touch detection of a user, wherein the electrode configuration comprises
at least one transmitting electrode,
at least one receiving electrode, and
at least one first field measuring electrode,
   wherein a first alternating electrical signal can be applied to the at least one transmitting electrode in order to generate a first alternating electrical field which can be emitted at the at least one transmitting electrode, wherein the first alternating electrical field can at least partially couple into the at least one receiving electrode and into the at least one first field measuring electrode, wherein the first alternating electrical field coupled into the at least one receiving electrode is indicative of the gripping of the hand-held device with one hand of the user, and wherein the first alternating electrical field coupled into the at least one first field measuring electrode is indicative of the position of the hand-held device relative to the body of the user.

Furthermore, the electrode configuration may comprise one second field measuring electrode, wherein the first alternating electrical field can at least partially couple into the at least one second field measuring electrode, and wherein the first alternating electrical field coupled into the at least one second field measuring electrode is indicative of the position of the hand-held device relative to the body of the user.

The at least one first field measuring electrode can be arranged at a front side of the hand-held device and the at least one second field measuring electrode can be arranged at a back side of the hand-held device, wherein a first electrical variable tapped at the first field measuring electrode and a second electrical variable tapped at the second field measuring electrode are indicative of the position of the hand-held device relative to the body of the user.

The tapped first electrical variable and the tapped second electrical variable can be supplied to an evaluation device, which is coupled with the at least one first field measuring electrode and with the at least one second field measuring electrode, wherein the evaluation device is adapted to calculate a difference of the first electrical variable and the second electrical variable, wherein the difference is indicative of the position of the hand-held device relative to the body of the user.

The value of the difference can be smaller than zero in case the back side of the hand-held device is orientated towards the palm of a hand gripping the hand-held device and the value of the difference can be greater than zero in case the front side of the hand-held device is orientated towards the palm of a hand gripping the hand-held device.

The evaluation device may be further adapted to check whether the absolute value of the first electrical variable and the absolute value of the second variable value are larger than a first threshold value in case the absolute value of the difference of the first electrical variable and the second electrical variable is below a second threshold value.

Furthermore, a second alternating electrical signal can be applied to one of the two field measuring electrodes in order to generate a second alternating electrical field, which can be emitted at the field measuring electrode, to which a second alternating electrical signal is applied and which can couple into the respective other field measuring electrode of the two field measuring electrodes in case the absolute value of the difference of the first electrical variable and the second electrical variable is below a second threshold value.

The electrode configuration may further comprise at least one compensating electrode, to which a third alternating electrical signal can be applied in order to generate a third alternating electrical field, which can be emitted at the at least one compensating electrode, wherein the third alternating electrical field can at least partially couple into the at least one receiving electrode, and wherein the third alternating electrical field coupled into the at least one receiving electrode together with the coupled first alternating electrical field is indicative of the gripping of the hand-held device with the hand of the user.

Preferably, the third alternating electrical signal has a different phasing with regard to the first alternating electrical signal. The amplitude of the first alternating electrical signal is preferably larger than the amplitude of the third alternating electrical signal.

The at least one transmitting electrode and the at least one receiving electrode can preferably be arranged at the hand-held device relatively to one another in such a way that they are at least partially covered when gripping the hand-held device with a hand.

Furthermore, a hand-held device is provided, particularly a cell phone, with an electrode configuration according to the various embodiments, wherein
the at least one transmitting electrode is arranged at a first side wall of the hand-held device,
the at least one receiving electrode is arranged at a second side wall opposite to the first side wall of the hand-held device, and
the at least one first field measuring electrode is arranged at the front side or at the back side of the hand-held device.

The at least one first field measuring electrode can be arranged in the area of the gravity center of the hand-held device at the front side or at the back side of the hand-held device.

Furthermore, a method for the detection of a touch of a hand-held device by a user is provided, wherein the method comprises at least the following steps:
applying a first alternating electrical signal to at least one transmitting electrode in order to generate a first alternating electrical field which can be emitted at the at least one transmitting electrode, wherein the first alternating electrical field can at least partially couple into the at least one receiving electrode and into the at least one first field measuring electrode,
evaluating a first electrical signal tapped at the first field measuring electrode, which is a measure of the capacitive coupling between the at least one transmitting electrode and the at least one first field measuring electrode,
evaluating a third electrical signal tapped at the receiving electrode, which is a measure of the capacitive coupling between the at least one transmitting electrode and the at least one receiving electrode,
   wherein
the first electrical signal is indicative of the position of the hand-held device relative to the body of the user, and
the third electrical signal is indicative of the gripping of the hand-held device with one hand of the user.

The first alternating electrical field can couple into at least one second field measuring electrode, wherein the method further comprises:
evaluating a second electrical signal tapped at the second field measuring electrode, and
determining a difference of the first electrical signal and the second electrical signal, wherein the difference is indicative of the position of the hand-held device relative to the body of the user.

Furthermore, the method may comprise:
applying a third alternating electrical signal to at least one compensating electrode, thus generating a third alternating electrical field which can be emitted at the at least one compensating electrode, which can couple into the at least one receiving electrode together with the first alternating electrical field.

The at least one receiving electrode can be switched over into a transmitting mode once the gripping of the hand-held device with a hand has been detected, wherein a fourth alternating electrical signal is applied to the at least one receiving electrode in the transmitting mode in order to emit a fourth alternating electrical field at the at least one receiving electrode, which can couple into at least one of the field measuring electrodes. This way the detection accuracy can be further enhanced.

Furthermore, at least one of the field measuring electrodes can be operated in a transmitting mode, in which an alternating electrical signal is applied to the field measuring electrode in order to emit an alternating electrical field, which can couple into the other field measuring electrode.

### BRIEF DESCRIPTION OF THE DRAWINGS

Further details and features of the various embodiments can be taken from the following description in combination with the drawings. The drawings show:

FIG. 1 an electrical hand-held device with an exemplary arrangement of electrodes of an electrode configuration;

FIG. 2 a block diagram of an electrode configuration according to various embodiments with an analysis device; and

FIG. 3a and FIG. 3b a side view of an electrical hand-held device, each with a different number of electrodes of the electrode configuration according to various embodiments.

### DETAILED DESCRIPTION

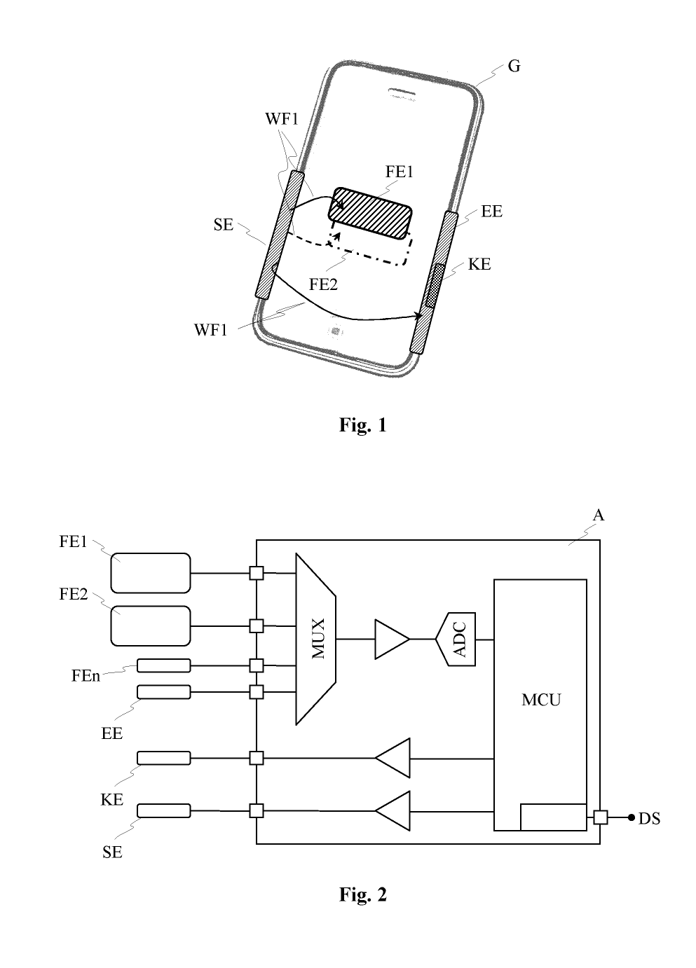

FIG. 1 exemplarily shows the arrangement of electrodes of an electrode configuration according to various embodiments at an electrical hand-held device G. A transmitting electrode SE is arranged at the left side of the cell phone G. A receiving electrode EE and a compensating electrode KE are arranged at the right side of the cell phone G. The transmitting electrode SE, the compensating electrode KE and the receiving electrode EE of the electrode configuration are provided for the detection of a gripping of the hand-held device G with one hand.

The electrodes SE, EE and KE are arranged at the side walls of the hand-held device G, respectively, in such a way that when gripping the hand-held device with a hand they are at least partially covered. A first alternating electrical signal is applied to the transmitting electrode SE in order to generate a first alternating electrical field WF1 emitted at the transmitting electrode SE. When the hand-held device G is gripped with one hand, the first alternating electrical field WF1 emitted at the transmitting electrode SE couples into the receiving electrode EE via the hand.

Due to the arrangement of the electrodes SE or EE at the side wall of the handheld device G, it is ensured that there is no erroneous detection when the electrical hand-held device G is put on an (electrically conductive) surface, i.e. putting the hand-held device G onto a surface does not misleadingly lead to a detection of a gripping of the hand-held device. Since the electrodes SE and EE are arranged at the side wall of the hand-held device, only a small part of the alternating electrical field WF1 emitted at the transmitting electrode SE couples into the receiving electrode EE via the surface.

The compensating electrode KE is provided in order to further reduce the risk of an erroneous detection. A third alternating electrical signal is applied to the compensating electrode KE. Preferably, the third alternating electrical signal has a different phasing with regard to the first alternating electrical signal. The amplitude of the third alternating electrical signal is preferably smaller than the amplitude of the first alternating electrical signal.

Applying the third alternating electrical signal to the compensating electrode KE leads to an emission of a third alternating electrical field at the compensating electrode KE, which couples into the receiving electrode EE. Preferably, the compensating electrode KE is arranged relatively to the receiving electrode EE at the hand-held device G in such a way that the third alternating electrical field emitted at the compensating electrode KE even couples into the receiving electrode EE when the electrical hand-held device G is not gripped with a hand. When the hand-held device G is put on an (electrically conductive) surface and a small part of the alternating electrical field emitted at the transmitting electrode SE couples into the receiving electrode EE via the surface, this alternating electrical field is almost eliminated by the third alternating electrical field emitted at the compensating electrode KE which has a different phasing and is preferably attenuated. This increase in level of an electrical current measured in the receiving electrode EE, resulting from the coupled first alternating field and the coupled third alternating field, is so small that an erroneous detection of a gripping can be almost completely avoided.

When the electrical hand-held device G is gripped by a hand in such a way that the hand at least partially covers the transmitting electrode SE and the receiving electrode EE, a part of the first alternating electrical field WF1 emitted at the transmitting electrode SE is coupled into the receiving electrode EE via the hand, wherein the first alternating field WF1, which is directly coupled into the receiving electrode EE is beyond the operating area of the compensating electrode KE. This leads to a significant increase in level of the electrical current measured at the receiving electrode EE, which is indicative of the gripping of the hand-held device with one hand.

Furthermore, a first field measuring electrode FE1 is arranged at the front side of the electrical hand-held device G. A second field measuring electrode FE2 is arranged at the back side of the electrical hand-held device G. Said two field measuring electrodes FE1 and FE2 are provided to detect an actual operation of the electrical hand-held device.

The first alternating electrical field WF1 emitted at the transmitting electrode SE also couples into the first field measuring electrode FE1 and into the second field measuring electrode FE2. When the electrical hand-held device G is gripped with a hand in such a way that the back side of the hand-held device G is turned towards the palm, the capacitive coupling between the transmitting electrode SE and the second field measuring electrode FE2 is higher than the capacitive coupling between the transmitting electrode SE and the first field measuring electrode FE1. As a result, the electrical current in the second field measuring electrode FE2 is considerably higher than the electrical current in the first field measuring electrode FE1. When a gripping of the hand-held device is detected, as described before, and when the electrical current in the second field measuring electrode FE2 is higher than the electrical current in the first field measuring electrode FE1, it can be concluded that the user intended to use the device.

However, when the electrical current in the first field measuring electrode FE1 is higher than the electrical current in the second field measuring electrode FE2, it can be concluded that the front side of the electrical hand-held device G is turned towards the palm of the hand gripping the hand-held device G. This situation can be clearly assigned to a non-operation.

The evaluation may be performed by, for example, comparing the two electrical currents in the field measuring electrodes FE1 and FE2. As an alternative, the difference of the electrical currents in the first field measuring electrode FE1 and in the second field measuring electrode FE2 can be calculated. When the difference of the two currents in the field measuring electrodes FE1 and FE2 is below zero, the back side of the hand-held device G is turned towards the palm of hand, whereas the front side of the hand-held device G is turned towards the palm of hand, when the difference of the currents is greater than zero.

Preferably, the currents in the field measuring electrodes FE1 and FE2 or the difference of said currents is only determined when a gripping of the electrical handheld device G is detected. This way, it is avoided that an intended use is erroneously detected, which could, for example, be the case when the back side of the electrical hand-held device G is put onto an electrically conductive surface. In this case, the electrical current in the second field measuring electrode FE2 would be considerably higher than the electrical current in the first field measuring electrode FE1.

This means that the field measuring electrodes FE1 and FE2 or the evaluation of the electrical currents at the field measuring electrodes FE1 and FE2 are only activated when a gripping of the electrical hand-held device is detected.

The electrodes SE, EE and KE provided for the detection of the gripping can be operated in a second operating mode in order to further enhance the precision of the detection for detecting the intended use. In the second operating mode, the receiving electrode EE can be operated as additional transmitting electrode, at which the first alternating field WF1 can also be emitted. This way, the first alternating electrical field WF1 is emitted at both sides of the electrical hand-held device, which couples into the field measuring electrodes FE1 or FE2 via the hand. This way, it is avoided that there is no or only a low coupling between the transmitting electrode SE and the field measuring electrodes FE1 or FE2 in case of unfavorable gripping of the hand-held device with the hand.

According to an embodiment, it is sufficient to provide only one of the two field measuring electrodes FE1 or FE2. For example, it can be sufficient to provide only the first field measuring electrode FE1 being arranged at the front side of the electrical hand-held device. When the electrical current measured at the first field measuring electrode FE1 reaches a predetermined threshold value, it can be concluded that the electrical hand-held device G is gripped by the hand in such a way that the front side of the hand-held device G is turned towards the palm of hand.

Conversely, when only the second field measuring electrode FE2 is provided at the back side of the hand-held device G and in case the electrical current measured at the second field measuring electrode FE2 exceeds a predetermined threshold value, it can be concluded that the electrical hand-held device G is gripped by the hand in such a way that the back side is turned towards the palm of hand.

When the electrical hand-held device, such as a cell phone, is wedged between a shoulder and the head, it may happen that the capacitive coupling between the transmitting electrode SE and the first field measuring electrode FE1 is almost identical to the capacitive coupling between the transmitting electrode SE and the second field measuring electrode FE2. In this case, the difference of the electrical currents measured in the field measuring electrodes FE1 and FE2 would be almost zero, so that a comparison of the electrical currents measured in the field measuring electrodes FE1 and FE2 or the calculation of the difference of said electrical currents would not lead to the desired result. In order to reliably detect also this case, it is advantageous to determine the absolute values of the electrical currents at the field measuring electrodes FE1 and FE2 in addition to the comparison of the electrical currents or the calculation of the difference. In case the currents measured in the field measuring electrode FE1 and FE2 exceed a predetermined threshold value, respectively, and in case a gripping of the electrical hand-held device has been detected, it can be concluded that not only the front side but also the back side of the electrical hand-held device is surrounded by the body of the user, which is for example the case when the hand-held device G is wedged between shoulder and head.

In case the electrical currents measured in the field measuring electrodes do not exceed said predetermined threshold value after a gripping of the hand-held device has been detected, it can be concluded that there is no intention of using the hand-held device.

FIG. 2 shows a block diagram of a capacitive sensor device with an electrode configuration according to various embodiments. The sensor device comprises an evaluation circuit A as well as the electrodes of the electrode configuration according to various embodiments which are connected to the evaluation circuit A. The transmitting electrode SE and the compensating electrode KE are each coupled with a microcontroller unit MCU via an amplifier circuit. With the microcontroller unit MCU an alternating electrical signal is applied to each of the transmitting electrode SE and the compensating electrode KE, wherein the alternating electrical signal applied to the compensating electrode KE preferably has a different phasing with regard to the alternating electrical signal applied to the transmitting electrode SE. Preferably, the alternating electrical signal applied to the compensating electrode has a smaller amplitude than the alternating electrical signal applied to the transmitting electrode SE.

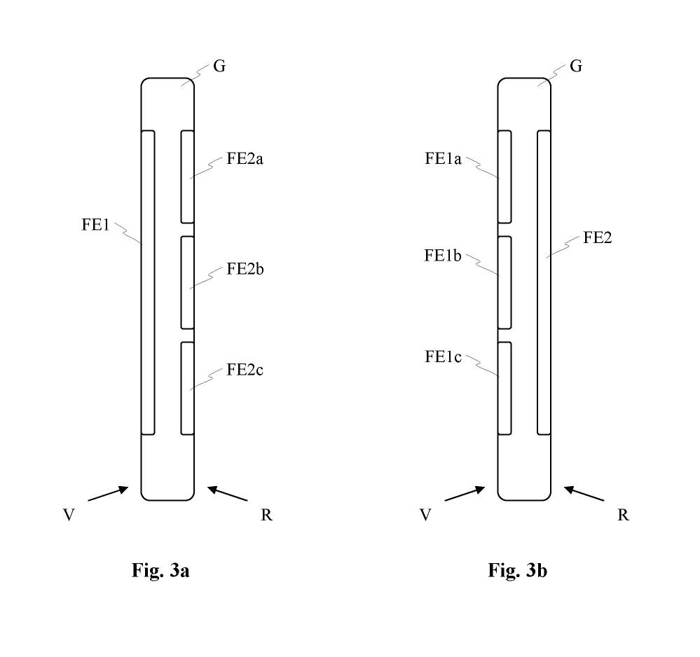

The embodiment according to FIG. 2 shows the receiving electrode EE as well as the field measuring electrodes FE1 and FE2, which are coupled with the micro-controller unit via a multiplexer MUX, an amplifier and an analog digital converter ADC. The electrical signals tapped at the receiving electrode EE as well as at the field measuring electrodes FE1 and FE2 are supplied to the microcontroller unit MCU and are evaluated there as described with reference to FIG. 1. A further field measuring electrode FEn can be provided in addition to the first field measuring electrode FE1 and the second field measuring electrode FE2 in order to determine the position of the electrical hand-held device G relative to the palm of a hand gripping the hand-held device. Embodiments of this are shown in FIGS. 3a and 3b.

The evaluation device A provides a detection signal DS at an output comprising information on the position of the hand-held device relative to the palm of hand. The evaluation device A can be, for example, implemented as application specific integrated circuit (ASIC). As an alternative, the analysis device A can also be integrated in a microcontroller, for example of a cell phone.

Each of FIGS. 3a and 3b show a side view of an electrical hand-held device G. The transmitting electrode SE, the compensating electrode KE and the receiving electrode EE are not illustrated in said figures. Only the arrangement of the field measuring electrodes at the front side V or at the back side R of the hand-held device G is illustrated.

FIG. 3a shows a hand-held device G with a first field measuring electrode FE1 arranged at the front side and with three second field measuring electrodes FE2a, FE2b and FE2c arranged at the back side. When gripping the hand-held device G, thus it is possible to additionally determine the position of the hand-held device relative to the palm of a hand gripping the hand-held device. For example, when the lower section of the hand-held device is gripped with a hand, the capacitive coupling between the transmitting electrode SE and the third field measuring electrode FE2c is higher than the capacitive coupling between the transmitting electrode SE and the upper field measuring electrode FE2a, so that also the electrical current measured at the lower field measuring electrode FE2c is higher than the electrical current measured at the upper field measuring electrode FE2a.

FIG. 3b also shows a side view of an electrical hand-held device G, with, unlike FIG. 3a, three first field measuring electrodes FE1a, FE1b and FE1c being arranged at the front side V and with only one second field measuring electrode FE2 being arranged at the back side R. This arrangement of the first field measuring electrodes also makes it possible to detect the position of the hand-held device relative to the palm of the hand gripping the hand-held device.

Furthermore, several field measuring electrodes can be arranged at the front side V and the back side R, respectively.

The field measuring electrodes can also be operated in an operating mode, using at least one of the field measuring electrodes as transmitting electrode. For example, the first field measuring electrode FE1 arranged at the front side of the handheld device G can be operated as transmitting electrode. A second alternating electrical signal is applied to the field measuring electrode being operated as transmitting electrode, such as the first field measuring electrode FE1, in order to generate an alternating electrical field, which is emitted at the field measuring electrode being operated as transmitting electrode. The emitted alternating electrical field can couple into the other field measuring electrode, such as the second field measuring electrode FE2, being arranged at the back side of the hand-held device G.

After the detection of a gripping of a hand-held device G with a hand, the electrical signals tapped at the field measuring electrodes are analyzed according to various embodiments in order to detect the position of the hand-held device G relative to the body of the user.

When the electrical hand-held device G is wedged between a shoulder and the head of the user during use, this could cause the capacitive coupling between the transmitting electrode SE and the receiving electrode EE to fall below a predetermined threshold value, which is indicative of a non-gripping of the hand-held device G. However, to be able to determine whether the hand-held device G is still in use, one of the field measuring electrodes is operated as transmitting electrode, after the value has fallen below the threshold value. For example, the first field measuring electrode FE1 is operated as transmitting electrode. When the electrical hand-held device G is wedged between a shoulder and the head of the user, a part of the alternating electrical field emitted at the first field measuring electrode FE1 couples into the second field measuring electrode FE2 via the body of the user.

When the electrical current measured at the second field measuring electrode FE2 exceeds a predetermined threshold value, it can be assumed that the hand-held device G is still in use although it is not gripped by a hand.

When the electrical current measured at the second field measuring electrode FE2 is below the predetermined threshold value, it can be assumed that the hand-held device G is no longer in use. The hand-held device G can, for example, be put to a sleep mode.

Furthermore, the second field measuring electrode FE2 can be operated as transmitting electrode.

A cell phone has been described above representative of an electrical hand-held device G. A hand-held device G, which can be provided with an electrode configuration according to various embodiments, can also be a computer mouse, a remote control for a device, a digital camera, a game controller, a personal digital assistant (PDA), a smart phone, a tablet PC or the like.

What is claimed is:

1. An electrode configuration for a capacitive sensor device of a hand-held device for the touch detection of a user, wherein the electrode configuration comprises
at least one transmitting electrode,
at least one receiving electrode, and
at least one first field measuring electrode,
wherein
a first alternating electrical signal can be applied to the at least one transmitting electrode in order to generate a first alternating electrical field emitted at the at least one transmitting electrode,
the first alternating electrical field can at least partially couple into the at least one receiving electrode and into the at least one first field measuring electrode,
the first alternating electrical field coupled into the at least one receiving electrode is indicative of the gripping of the hand-held device with one hand of the user, and
the first alternating electrical field coupled into the at least one first field measuring electrode is indicative of the position of the handheld device relative to the body of the user.

2. An electrode configuration according to claim 1, wherein the electrode configuration further comprises at least one second field measuring electrode, wherein the first alternating electrical field can at least partially couple into the at least one second field measuring electrode, and wherein the first alternating electrical field coupled into the at least one second field measuring electrode is indicative of the position of the hand-held device relative to the body of the user.

3. An electrode configuration according to claim 2, wherein the at least one first field measuring electrode can be arranged at a front side of the hand-held device and the at least one second field measuring electrode can be arranged at a back side of the hand-held device, wherein a first electrical variable tapped at the first field measuring electrode and a second electrical variable tapped at the second field measuring electrode are indicative of the position of the hand-held device relative to the body of the user.

4. An electrode configuration according to claim 3, wherein the tapped first electrical variable and the tapped second electrical variable can be supplied to an evaluation device, which is coupled with the at least one first field measuring electrode and with the at least one second field measuring electrode, wherein the evaluation device is adapted to calculate a difference of the first electrical variable and the second electrical variable, wherein the difference is indicative of the position of the hand-held device relative to the body of the user.

5. An electrode configuration according to claim 4, wherein the value of the difference is smaller than zero in case the back side of the hand-held device is orientated towards the palm of a hand gripping the hand-held device, and wherein the value of the difference is greater than zero in case the front side of the hand-held device is orientated towards the palm of a hand gripping the hand-held device.

6. An electrode configuration according to claim 4, wherein the evaluation device is further adapted to check whether the absolute value of the first electrical variable and the absolute value of the second variable are larger than a first threshold value in case the absolute value of the difference of the first electrical variable and the second electrical variable is below a second threshold value.

7. An electrode configuration according to claim 4, wherein a second alternating electrical signal can be applied to one of the two field measuring electrodes in order to generate a second alternating electrical field, which can be emitted at the field measuring electrode, to which the second alternating electrical signal is applied and which can couple into the respective other field measuring electrode of the two field measuring electrodes in case the absolute value of the difference of the first electrical variable and the second electrical variable is below a second threshold value.

8. An electrode configuration according to claim 1, wherein the electrode configuration further comprises at least one compensating electrode, to which a third alternating electrical signal can be applied, thus generating a third alternating electrical field, which can be emitted at the at least one compensating electrode, wherein the third alternating electrical field can at least partially couple into the at least one receiving electrode, and wherein the third alternating electrical field coupled in the at least one receiving electrode together with the coupled first alternating electrical field are indicative of the gripping of the hand-held device with the hand of the user.

9. An electrode configuration according to claim 8, wherein the third alternating electrical signal has a different phasing with regard to the first alternating electrical signal and wherein the amplitude of the first alternating electrical signal is larger than the amplitude of the third alternating electrical signal.

10. An electrode configuration according to claim 1, wherein the at least one transmitting electrode and the at least one receiving electrode can be arranged at the hand-held device relatively to one another in such a way that they are at least partially covered when gripping the hand-held device with a hand.

11. A hand-held device with an electrode configuration according to claim 1, wherein the at least one transmitting electrode, the at least one receiving electrode and the at least one first field measuring electrode are arranged at a housing wall of the hand-held device, wherein the first field measuring electrode is arranged between the transmitting electrode and the receiving electrode.

12. A hand-held device according claim 11, wherein
the at least one transmitting electrode is arranged at a first side wall of the hand-held device,
the at least one receiving electrode is arranged at a second side wall opposite to the first side wall of the hand-held device, and
the at least one first field measuring electrode is arranged at the front side or at the back side of the hand-held device.

13. A hand-held device according to claim 11, wherein the at least one first field measuring electrode is arranged in the area of the gravity center of the hand-held device at the front side or at the back side of the hand-held device.

14. A hand-held device according to claim 11, wherein the hand-held device comprises at least one of a mobile radio unit, a cell phone, a computer mouse, a remote control for a device, a digital camera, a game controller, a mobile personal digital assistant, a smart phone, and a tablet PC.

15. A method for the detection of a touch of a hand-held device by a user, wherein the method comprises at least the following steps:
applying one first alternating electrical signal to at least one transmitting electrode in order to generate a first alternating electrical field, which can be emitted at the at least one transmitting electrode, wherein the first alternating electrical field can at least partially couple into the at least one receiving electrode and into at least one first field measuring electrode,
evaluating a first electrical signal tapped at the first field measuring electrode, which is a measure of the capacitive coupling between the at least one transmitting electrode and the at least one first field measuring electrode,
evaluating a third electrical signal tapped at the receiving electrode, which is a measure of the capacitive coupling between the at least one transmitting electrode and the at least one receiving electrode,
wherein
the first electrical signal is indicative of the position of the hand-held device relative to the body of the user, and
the third electrical signal is indicative of the gripping of the hand-held device with one hand of the user.

16. A method according to claim 15, wherein the first alternating electrical field can couple into at least one second field measuring electrode, and wherein the method further comprises:
evaluating a second electrical signal tapped at the second field measuring electrode,
determining a difference of the first electrical signal and the second electrical signal, wherein the difference is indicative of the position of the hand-held device relative to the body of the user.

17. A method according to claim 15, wherein the method further comprises:
applying a third alternating electrical signal to at least one compensating electrode, thus generating a third alternating electrical field, which can be emitted at the at least one compensating electrode, and which can couple into the at least one receiving electrode together with the first alternating electrical field.

18. A method according to claim 15, wherein the at least one receiving electrode is switched over into a transmitting mode once the gripping of the hand-held device with the hand has been detected, wherein a fourth alternating electrical signal is applied to the at least one receiving electrode in the transmitting mode in order to emit a fourth alternating electrical field at the at least one receiving electrode, which can couple into at least one of the field measuring electrodes.
